(19) United States
(12) Patent Application Publication
(10) Pub. No.: US 2008/0237881 A1
(43) Pub. Date: Oct. 2, 2008

(54) RECESSED SOLDER SOCKET IN A SEMICONDUCTOR SUBSTRATE

(76) Inventors: Tony DAMBRAUSKAS, Mesa, AZ (US); Randall L. Lyons, Chandler, AZ (US)

Correspondence Address: KONRAD RAYNES & VICTOR, LLP.;ATTN: INT77, 315 SOUTH BEVERLY DRIVE, SUITE 210, BEVERLY HILLS, CA, 90212, US

(21) Appl. No.: 11/694,923

(22) Filed: Mar. 30, 2007

(51) Int. Cl. H01L 23/52

(52) U.S. Cl. 257/774; 257/E23.141

(57) ABSTRACT

Electronic devices and their formation are described. In one embodiment, a device includes a plurality of stacked semiconductor substrates. The device includes a first semiconductor substrate having a recess extending into a first surface thereof and a via extending from the recess to a second surface opposite the first surface of the first semiconductor substrate. The device also includes a solder positioned in the recess of the first semiconductor substrate. The device also includes an electrically conducting material in the via and electrically coupled to the solder positioned in the recess of the first semiconductor substrate. The device also includes a second semiconductor substrate having bonding pad extending therefrom, the bonding pad electrically coupled to the solder. The device is configured so that at least a portion of the second substrate bonding pad extends a distance into the recess in the first substrate. Other embodiments are described and claimed.

### RELATED ART

Integrated circuits may be formed on semiconductor wafers that are formed from materials such as silicon. The semiconductor wafers are processed to form various electronic devices thereon. The wafers may be diced into semiconductor chips, and attached to another structure such as another semiconductor chip. When stacking multiple chips, the chips may be attached using a method in which solder bumps are placed on metal pads formed on the chip. The solder bumps are melted and permitted to flow, to ensure that each bump fully wets the associated pad and forms a suitable bond between the chips. An underfill material such as a polymer may then be inserted between the chips using, for example, a capillary action method. The underfill acts to protect the bumps bonds and may also act to provide support for the upper substrate(s).

### BRIEF DESCRIPTION OF THE DRAWINGS

Embodiments are described by way of example, with reference to the accompanying drawings, which are not drawn to scale, wherein:

FIG. 1 illustrates a semiconductor substrate including a recessed region and a via extending through the semiconductor substrate, in accordance with certain embodiments;

FIG. 2 illustrates the semiconductor substrate of FIG. 1, including a solder positioned in the recess and a bonding pad positioned on a surface of the semiconductor substrate at one end of the via, in accordance with certain embodiments;

FIG. 3 illustrates a stacked semiconductor substrate structure in which a bonding pad coupled to one substrate is aligned with the recess in another substrate, in accordance with certain embodiments;

FIG. 4 illustrates a flow chart including processing operations for forming an electronic device, in accordance with certain embodiments.

FIGS. 5(A)-5(F) illustrate processing operations for forming an electronic device, in accordance with certain embodiments;

FIGS. 6(A) and 6(B) illustrate the position of a recessed region and a via, in accordance with certain embodiments;

FIG. 7 illustrates an electronic system arrangement in which certain embodiments may find application.

### DETAILED DESCRIPTION

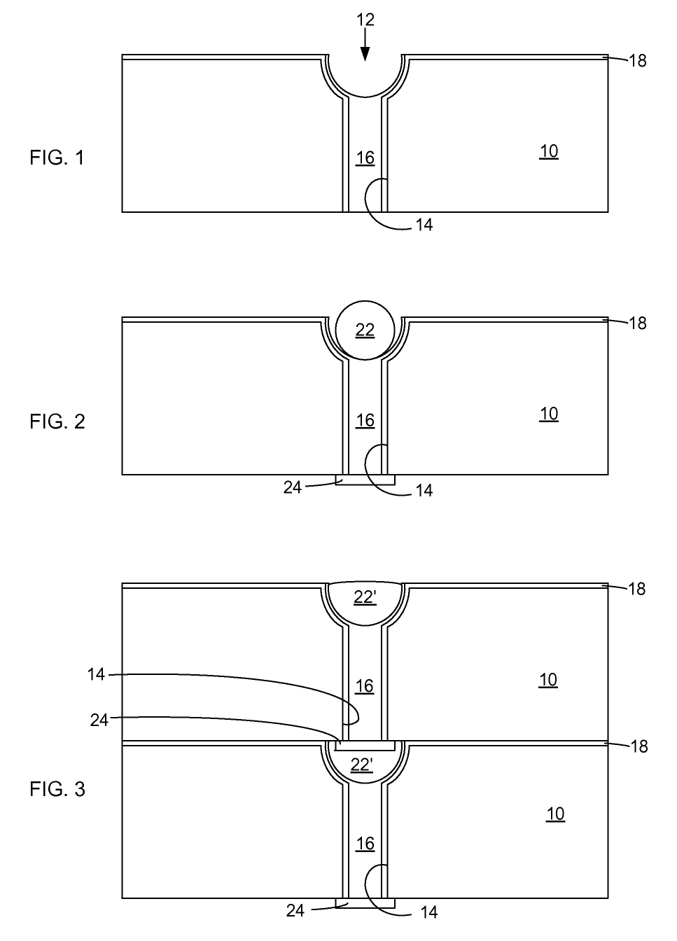

FIG. 1 illustrates a substrate formed in accordance with certain embodiments. The substrate 10 may be a semiconductor substrate formed from, for example, silicon. A recess 12 is formed in the substrate 10. The recess 12 may, as illustrated in FIG. 1, have a bowl shape. Another way to describe the shape of the recess 12 in FIG. 1 is a hemispherical shape. Other shapes may also be formed, depending, for example, on the etchant used and the crystal orientation of the semiconductor substrate. The recess 12 may be formed using, for example, an isotropic etching process. The substrate 10 includes a via 14 extending from the recess 12 through the thickness of the substrate 1O. The via 14 may be formed using, for example, an anisotropic etching process. The via 14 may including a electrically conducting layer 16 positioned therein. An electrically insulating layer 18 may be formed between the electrically conducting layer 16 in the via and the walls of the substrate 10 that define the via 14. The electrically insulating layer 18 may also be formed on the substrate in the recess and along an upper surface of the substrate 10 as illustrated in FIG. 1. One or more thin layers (not shown in FIG. 1) may be formed between the electrically conducting layer 16 and the electrically insulating layer 18 in the recess 12 and via 14, to act as a barrier layer and to promote the formation of the electrically conducting layer 16.

The recess 12 of the embodiment illustrated in FIG. 1 is sized to accept a bonding pad extending at least partially therein, as will be discussed below in connection with FIGS. 2-3. FIG. 2 illustrates the substrate 10 of FIG. 1, further including a solder region 22 positioned within the recess 12. The solder region 22 may in certain embodiments be in the form of a bump or ball. FIG. 2 also illustrates a bonding pad 24 positioned at an end of the via 14. The bonding pad 24 is electrically coupled to the electrically conducting layer 16 in the via.

FIG. 3 illustrates two stacked substrates 10 in alignment with one another, each having a structure such as that illustrated in FIG. 2, after a heating operation has been carried to reflow the solder 22 to form reflowed solder 22′. As seen in FIG. 3, the upper substrate 10 includes the bonding pad 24 coupled to the metal 16 in the via 14. At least a portion of the pad 24 is positioned within the recess of the substrate 110, in contact with the reflowed solder 122′. The reflowed solder 122′ wets the solder pad 24 and forms a suitable bond therewith.

The structure of the embodiment of FIG. 3 may provide one or more advantages when compared with conventional attachment schemes for coupling substrates together in a stack. For instance, by positioning at least a portion of the bonding pad 24 in the recess of the substrate 10, the distance between the substrates 10 can be minimized, thus saving vertical space in the assembly structure. In addition, as seen in FIG. 2, for example, the presence of the recess may permit relatively easy positioning of the solder 22 on the via 16, because the shape of the recess may act to self-align the solder 22 within the recess 12. In addition, any gap between the substrates 10 is minimized, thus minimizing or eliminating the need for an underfill material between the substrates 10. While two substrates are shown stacked in FIG. 3, it should be appreciated that more than two substrates may be stacked if desired.

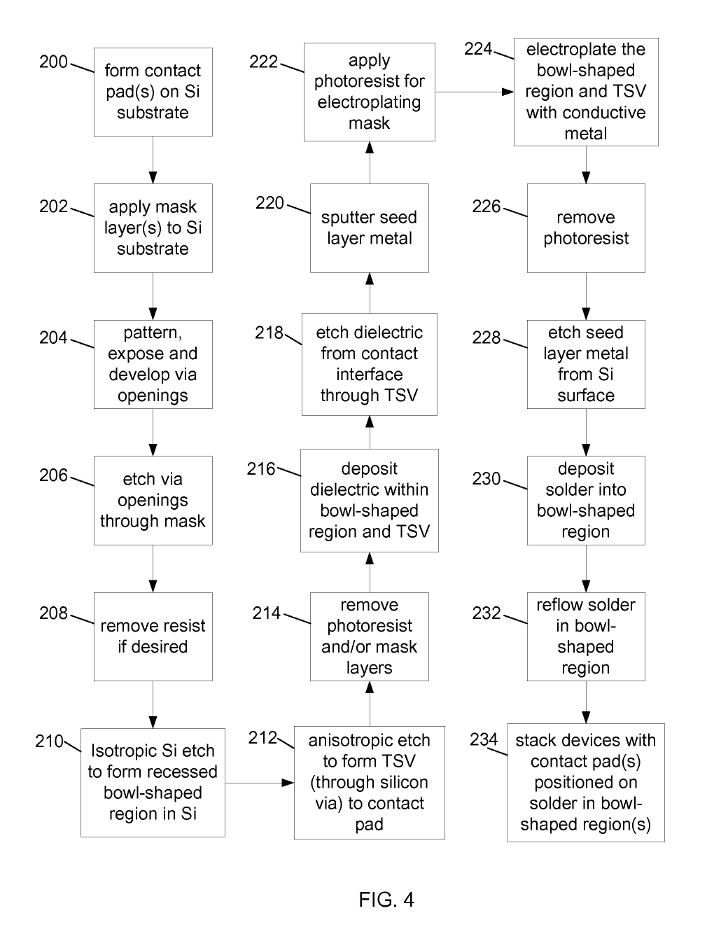

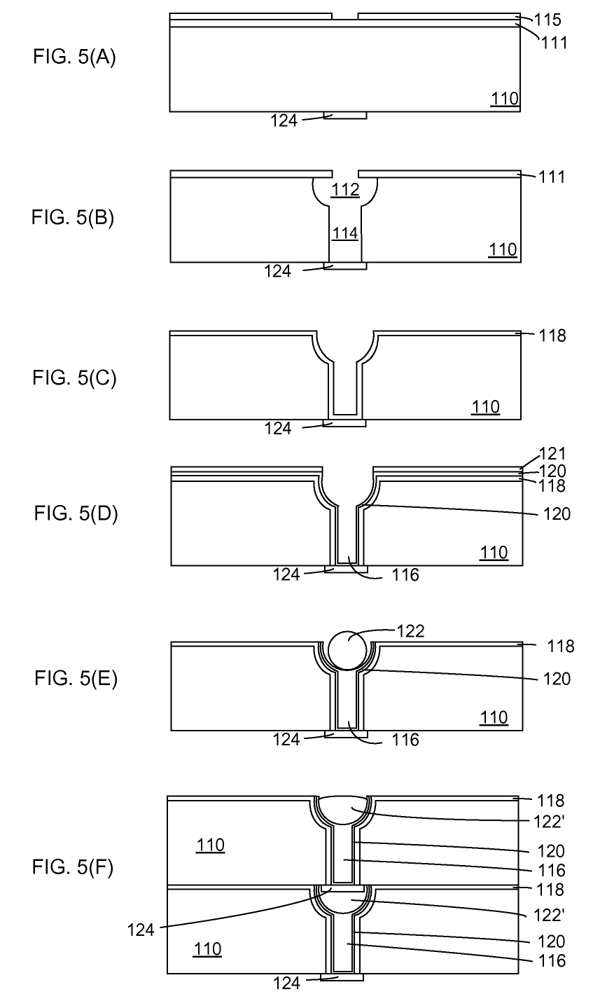

A detailed description of a process for forming an electronic assembly including a stack of silicon substrates, in accordance with certain embodiments, will be discussed in connection with the flow chart of FIG. 4 and the process operations of FIGS. 5(A)-5(F). Box 200 of FIG. 4 is providing a silicon substrate 110. The substrate 110 may include one or more bonding pads 124 formed thereon. Box 202 is forming a mask layer on the substrate 110. The mask layer may include one or more layers, and may include a hard mask layer 111 (for example, an oxide or nitride material) and/or a photoresist mask layer 115, depending on the subsequent method of processing (e.g., dry etching or wet etching). When a photoresist layer 115 on top of a hard mask layer 111 is used, Box 204 is patterning, exposing, and developing via openings in the photoresist layer 115, as seen in FIG. 4(A). Box 206 is etching via openings in the hard mask layer 111. Box 208 is removing the resist mask if desired, which leaves a hard mask on the silicon substrate.

Box 210 is isotropically etching the silicon substrate 110 through the hard mask layer 111. The isotropic etching may be a wet or dry process, and may be timed to control the depth of the etching. Such isotropic etching may form a hemispherical (bowl-shaped) recess 112 in the silicon substrate 110. Box 212 is anisotropically etching the silicon substrate 111 to form a through-silicon via 114 extending from a bottom region of the recess 112 to the other side of the substrate 110. The through-silicon via may be etched through the existing mask, and be configured to extend from the recess 112 to the bonding pad 124, as illustrated in FIG. 5(B).

Box 214 is removing the remaining mask layers, which may include one or more of photoresist mask layer 115 and hard mask layer 111. Box 216 is forming a dielectric layer 118 within the recessed region, the through-silicon via, and on the substrate 110 surface, as illustrated in FIG. 5(C). The dielectric layer 118 may act to electrically isolate the recess 112 and via 114 after they are filled with conductive material. The dielectric layer 118 may be, for example, silicon dioxide (SiO₂). Box 218 is etching to remove part of the silicon dioxide layer 118 that was formed on the contact pad 124 through the via 114. This permits a good electrical contact to be made between the contact pad 124 and the electrically conductive fill material to be placed in the via 114.

To form an electrically conducting material in the via 114, a metal may be formed therein. The term metal as used herein includes pure metals and alloys. One method for forming the metal in the via is to sputter a seed layer 120 of one or more layers of material that coat the silicon dioxide layer in the recess 112 and through-hole via 114, as indicated in Box 220. The seed layer 120 is illustrated in FIG. 5(D). The seed layer 120 may also extend over the surface of the silicon substrate 110 during at least some of the subsequent process operations. In certain embodiments the seed layer 118 may act as a barrier layer and may also act to facilitate an electroplating process. Examples of materials that may be used as the one or more layers of the seed layer 118 include, but are not limited to, refractory metals as a barrier layer portion of the seed layer, and conductive metals (e.g. copper, gold) as a layer to promote a plating process. Box 222 is applying a photoresist layer and patterning the layer to form a photoresist mask 121 with an opening over the recess 112 and through-silicon via 114, as illustrated in FIG. 5(D). This photoresist mask 121 will serve as a mask during subsequent deposition of metal in the recess 112 and through-silicon via 114.

Box 224 is electroplating the recess 112 and through-silicon via 114 with a metal 116. Other suitable metal deposition techniques may be used. In certain embodiments, the seed layer 118 in the recess is coated but the entire recess is not filled with the electroplated metal 116. The through-silicon via 114 region extending to the contact pad 124 is filled with the electroplated metal 116, as illustrated in FIG. 5(E). Alternatively, a suitable plating process covering only the sidewalls defining the via 114 may be utilized. Box 226 is removing the photoresist mask 121. Box 228 is etching the seed layer 118 remaining on the silicon dioxide 118 on the silicon substrate 110 surface. Box 230 is depositing solder 122 into the recess. The solder is illustrated in FIG. 5(E). This may be accomplished using a variety of suitable methods, including, but not limited to, depositing solder bumps or applying solder paste using, for example, a squeegee method. The solder 122 may be in the form of a ball or bump, or may take any other shape within the recess 112.

Box 232 is heating the solder 122 in the recess to reflow the solder and yield reflowed solder 122′. In certain situations, depending on the height of the solder 122 in the recess, the solder 122 may be reflowed more than once, with a first reflow to flatten the solder profile, and the second reflow to couple a contact pad 124 to the solder. Box 234 is stacking the silicon substrates 110 with a contact pad 124 from an upper substrate 110 positioned on the reflowed solder 122′ in the recessed region 112 of the substrate 110 below it. The contact pad 124 may extend at least partially into the recessed region 112 of the lower substrate 110, as illustrated in FIG. 5(F). A stacked device formed in a manner such as described above will have little or no gap between the substrates 110. The silicon oxide layer 118 acts as an electrically insulating barrier between the stacked substrates 110 and may by patterned to form openings therein or even removed if desired. It should be appreciated that certain operations set forth in FIG. 4, and illustrated in FIGS. 5(A)-5(F), may be modified, the order changed, or deleted from the process as desired.

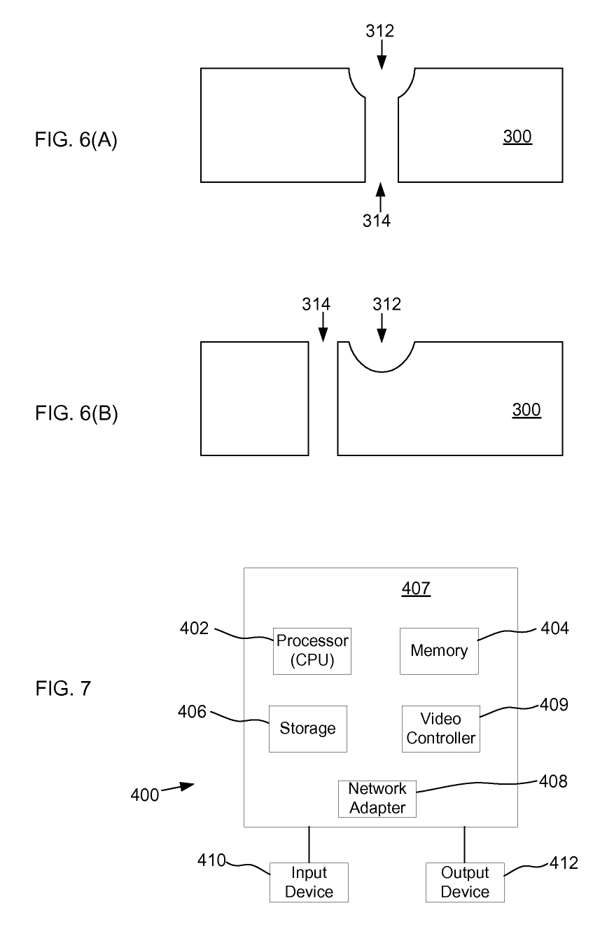

Embodiments are applicable to a variety of semiconductor substrate thicknesses including, but not limited to, semiconductor substrates having a thickness in the range of about 50-300 microns. In another aspect of certain embodiments, the position of the via extending through the substrate may be varied. For example, as illustrated in FIG. 6(A), a substrate 300 includes a recessed region 312 with a via region 314 extending from a bottom portion of the recessed region 312 to the lower surface of the substrate 300. The via region 314 is aligned with the central axis of the recessed region 312. FIG. 6(B) illustrates an embodiment in which the via region 314 is offset from the recessed region 312.

Assemblies as described in embodiments above may find application in a variety of electronic components. In certain embodiments, a device or devices in accordance with the present description may be embodied in a computer system including a video controller to render information to display on a monitor coupled to the computer. The computer system may comprise one or more of a desktop, workstation, server, mainframe, laptop, handheld computer, handheld gaming device, handheld entertainment device (for example, a video player), PDA (personal digital assistant), telephony device (wireless or wired), etc. Alternatively, a device or devices in accordance with the present description may be embodied in a computing device that does not include a video controller, such as a switch, router, etc.

FIG. 7 schematically illustrates one example of an electronic system environment in which aspects of described embodiments may be embodied. Other embodiments need not include all of the features specified in FIG. 7, and may include alternative features not specified in FIG. 7. FIG. 7 illustrates an embodiment of a device including a computer architecture 400 which may utilize integrated circuit devices having a structure including capacitors formed in accordance with embodiments as described above. The architecture 400 may include a CPU 402, memory 404 (including, for example, a volatile memory device), and storage 406 (including, for example, a non-volatile storage device, such as magnetic disk drives, optical disk drives, etc.). The CPU 402 may be coupled to a printed circuit board 407, which in this embodiment, may be a motherboard. The CPU 402 is an example of a device that may have devices formed in accordance with the embodiments described above and illustrated, for example in FIG. 5(F). A variety of other system components, including, but not limited to input/output devices, controllers, memory and other components, may also include structures formed in accordance with the embodiments described above. The system components may be formed on the motherboard, or may be disposed on other cards such as daughter cards or expansion cards.

The storage 406 may comprise an internal storage device or an attached or network accessible storage. Programs in the storage 406 may be loaded into the memory 404 and executed by the CPU 402 in a manner known in the art. The architecture may further include a network controller 408 to enable communication with a network, such as an Ethernet, a Fibre Channel Arbitrated Loop, etc. Further, the architecture may, in certain embodiments, also include a video controller 409, to render information on a display monitor, where the video controller may be embodied on a video card or integrated on integrated circuit components mounted on the motherboard, for example. Other controllers may also be present to control other devices.

An input device 410 may be used to provide input to the CPU 402, and may include, for example, a keyboard, mouse, pen-stylus, microphone, touch sensitive display screen, or any other suitable activation or input mechanism. An output device 412 including, for example, a monitor, printer, speaker, etc., capable of rendering information transmitted from the CPU 402 or other component, may also be present.

While certain exemplary embodiments have been described above and shown in the accompanying drawings, it is to be understood that such embodiments are merely illustrative and not restrictive, and that embodiments are not restricted to the specific constructions and arrangements shown and described since modifications may occur to those having ordinary skill in the art.

What is claimed:

1. A device comprising:
a semiconductor substrate; and
a recess extending into a surface thereof,
wherein the recess is sized to accept a bonding pad.

2. The device of claim 1, further comprising a solder material positioned in the recess.

3. The device of claim 2, further comprising a via extending from a portion of the recess to an opposite surface of the semiconductor substrate.

4. The device of claim 3, further comprising a metal positioned in the via, the metal in electrical contact with the solder.

5. The device of claim 4, further comprising a bonding pad coupled to another semiconductor substrate, the bonding pad positioned at least partially within the recess.

6. The device of claim 1, wherein the recess is bowl-shaped.

7. The device of claim 3, wherein the via has a width that is less than that of the recess.

8. The device of claim 3, further comprising an insulating layer lining at least a portion of the recess and the via.

9. The device of claim 8, further comprising a metal layer between the insulating layer and the solder in the recess.

10. The device of claim 8, wherein the semiconductor substrate comprises silicon, and the insulating layer comprises silicon dioxide, and wherein the semiconductor substrate includes a plurality of additional recesses extending into the surface and additional vias extending from the additional recesses to the opposite surface of the semiconductor substrate.

11. A device comprising:
a first semiconductor substrate having a recess extending into a first surface thereof and a via extending from the recess to a second surface opposite the first surface of the first semiconductor substrate;
a solder positioned in the recess of the first semiconductor substrate;
an electrically conducting material in the via and electrically coupled to the solder positioned in the recess of the first semiconductor substrate; and
a second semiconductor substrate having a bonding pad extending therefrom, the bonding pad electrically coupled to the solder;
wherein at least a portion of the bonding pad extends a distance into the recess.

12. The device of claim 11, wherein the semiconductor substrates comprise silicon.

13. The device of claim 11, further comprising an electrically insulating layer lining at least a portion of the recess and the via, wherein the electrically insulating layer is positioned between the solder and the substrate and the electrically insulating layer is also positioned between the electrically conducting material in the via and the semiconductor substrate.

14. The device of claim 11, wherein the electrically insulating layer extends between the first semiconductor substrate and the second semiconductor substrate, and wherein no polymer underfill material is positioned between the first semiconductor substrate and the second semiconductor substrate.

15. The device of claim 11, further comprising at least one additional semiconductor substrate stacked on the second semiconductor substrate.
